(19) United States
(12) Patent Application Publication
(10) Pub. No.: US 2025/0171895 A1
(43) Pub. Date: May 29, 2025

(54) Substrate Processing Apparatus, Cleaning Method, Method of Manufacturing Semiconductor Device and Non-transitory Computer-readable Recording Medium

(71) Applicant: Kokusai Electric Corporation, Tokyo (JP)

(72) Inventor: Yoshitomo HASHIMOTO, Toyama (JP)

(21) Appl. No.: 19/037,767

(22) Filed: Jan. 27, 2025

Related U.S. Application Data
(63) Continuation of application No. PCT/JP2023/011595, filed on Mar. 23, 2023.

(30) Foreign Application Priority Data
Aug. 1, 2022 (JP) 2022-123008

(51) Int. Cl. C23C 16/44; C23C 16/458; C23C 16/52

(52) U.S. Cl. CPC C23C 16/4405; C23C 16/4583; C23C 16/52

(57) ABSTRACT

There is provided a technique that includes: a process vessel in which a process substrate is capable of being processed; a substrate placement table on which the process substrate is placed; and a controller capable of controlling a cooling process and a cleaning process such that the cooling process of cooling an inner portion of the process vessel is performed with a cooling substrate placed on the substrate placement table when an inner temperature of the process vessel after processing the process substrate is higher than a temperature for the cleaning process of cleaning the inner portion of the process vessel, wherein an outer peripheral length of the cooling substrate is set to be shorter than that of the process substrate, and such that the cleaning process is performed when the inner temperature of the process vessel reaches a temperature at which the cleaning process is possible.

### CROSS REFERENCE TO RELATED APPLICATIONS

This application is a bypass continuation application of PCT International Application No. PCT/JP2023/011595, filed on Mar. 23, 2023, in the WIPO, the international application being based upon and claiming the benefit of priority from Japanese Patent Application No. 2022-123008, filed on Aug. 1, 2022, in the Japanese Patent Office, the entire contents of which are hereby incorporated by reference.

### TECHNICAL FIELD

The present disclosure relates to a substrate processing apparatus, a cleaning method, a method of manufacturing a semiconductor device and a non-transitory computer-readable recording medium.

### BACKGROUND

According to some related arts, as an example of a substrate processing apparatus, a substrate processing apparatus capable of performing a cleaning process may be used. In such a substrate processing apparatus, the cleaning process may be performed in a process vessel thereof. When a temperature during a substrate processing is higher than a temperature during the cleaning process, it is preferable that a temperature (inner temperature) of the process vessel is cooled to the temperature during the cleaning process. However, when a temperature of a substrate placement table provided in the substrate processing apparatus is high, it may take a long time to cool an inner portion of the process vessel.

### SUMMARY

According to the present disclosure, there is provided a technique capable of improving a substrate production efficiency by rapidly cooling a process vessel.

According to an embodiment of the present disclosure, there is provided a technique that includes: a process vessel in which a process substrate is capable of being processed; a substrate placement table on which the process substrate is capable of being placed; and a controller configured to be capable of controlling a cooling process and a cleaning process such that the cooling process of cooling an inner portion of the process vessel is performed with a cooling substrate placed on the substrate placement table when an inner temperature of the process vessel after processing the process substrate is higher than a temperature for the cleaning process of cleaning the inner portion of the process vessel, wherein an outer peripheral length of the cooling substrate is set to be shorter than that of the process substrate, and such that the cleaning process is performed when the inner temperature of the process vessel reaches a temperature at which the cleaning process is possible.

### BRIEF DESCRIPTION OF THE DRAWINGS

FIG. 1 is a diagram schematically illustrating a horizontal cross-section of a substrate processing apparatus according to one or more embodiments of the present disclosure.

FIG. 2 is a diagram schematically illustrating a vertical cross-section of the substrate processing apparatus according to the embodiments of the present disclosure.

FIG. 3 is a diagram schematically illustrating a configuration of a process furnace shown in FIG. 1.

FIG. 4 is a diagram schematically illustrating a configuration of a cooling substrate cooler shown in FIG. 1.

FIG. 5 is a block diagram schematically illustrating a configuration of a controller and related components of the substrate processing apparatus according to the embodiments of the present disclosure.

FIG. 6A is a diagram schematically illustrating a cross-section of a film formed on a susceptor.

FIG. 6B is a diagram schematically illustrating a relationship among a process substrate, a first cooling substrate, a second cooling substrate and a diameter of the film.

FIG. 7 is a diagram schematically illustrating a process table of a processing process.

FIG. 8 is a flow chart schematically illustrating a part of the processing process.

FIG. 9 is a flow chart schematically illustrating a part of the processing process.

FIG. 10 is a flow chart schematically illustrating a part of the processing process.

FIG. 11 is a flow chart schematically illustrating a part of the processing process.

### DETAILED DESCRIPTION

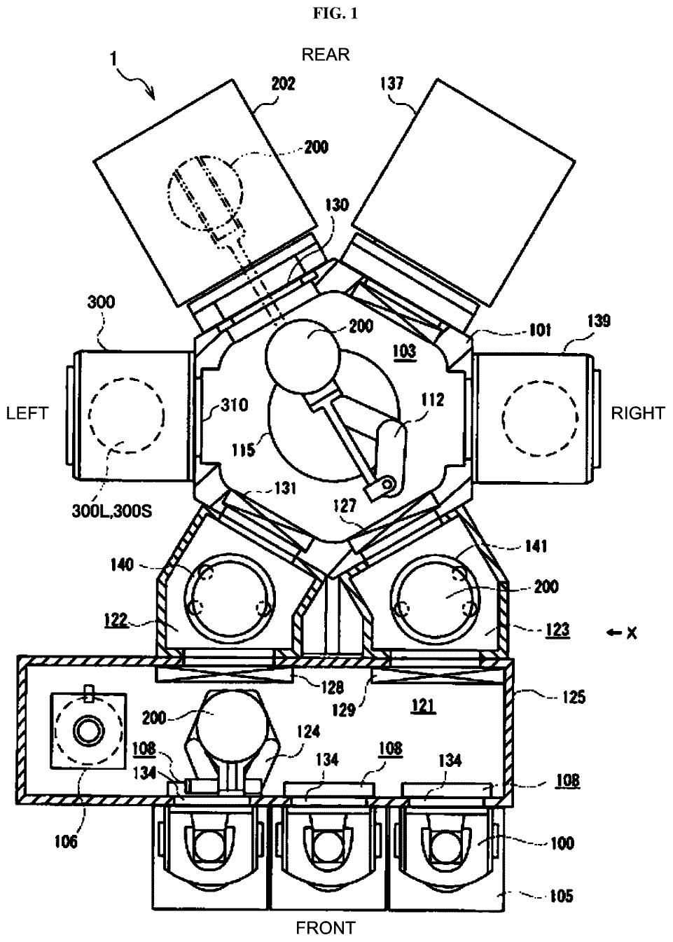

Hereinafter, one or more embodiments (also simply referred to as “embodiments”) according to the technique of the present disclosure will be described with reference to FIGS. 1 to 11. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, the same or similar reference numerals represent the same or similar components in the drawings.

### <Configuration of Substrate Processing Apparatus 1>

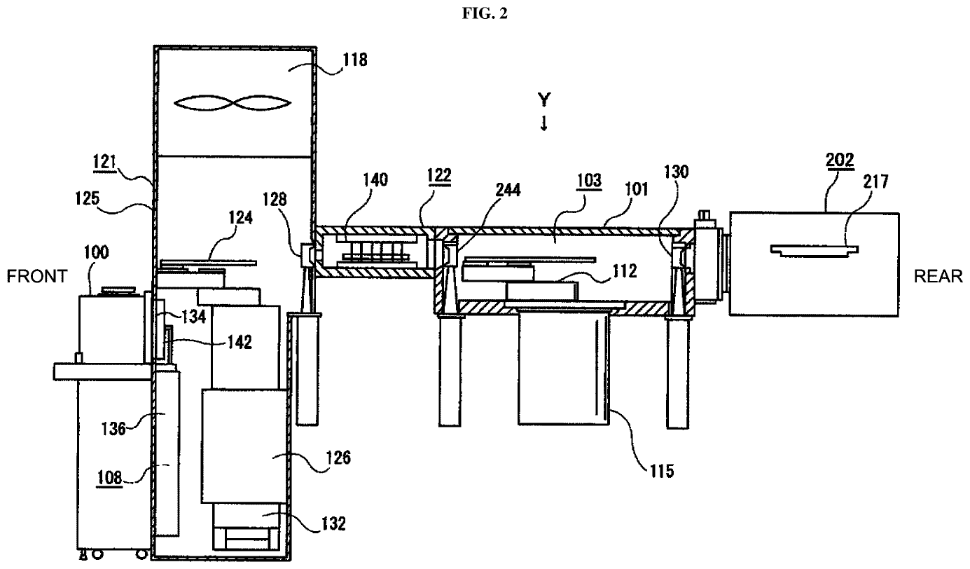

In the present embodiments, “FRONT”, “REAR”, “LEFT” and “RIGHT” shown in FIGS. 1 and 2 correspond to front, rear, left and right in the following description, respectively. In addition, FIG. 1 is a diagram schematically illustrating a configuration of a substrate processing apparatus 1 when viewed along a direction of an arrow Y shown in FIG. 2, and FIG. 2 is a diagram schematically illustrating the configuration of the substrate processing apparatus 1 when viewed along a direction of an arrow X shown in FIG. 1. In addition, in the substrate processing apparatus 1, a FOUP (front opening unified pod) is used as a carrier for transferring substrates such as wafers.

As shown in FIGS. 1 and 2, the substrate processing apparatus 1 includes a first transfer chamber 103 configured as a load lock chamber structure capable of withstanding a pressure (negative pressure) less than an atmospheric pressure, such as a vacuum state. Further, a housing 101 of the first transfer chamber 103 is of a box shape which is hexagonal when viewed from above with closed upper and lower ends. In the first transfer chamber 103, a first wafer transfer structure (vacuum transfer structure) 112 is installed as an example of a vacuum transfer apparatus configured to transfer a process substrate (wafer) 200 (on which a process is performed) under the negative pressure (vacuum state). The process substrate 200 according to the present embodiments is used as the wafer for a semiconductor device. The process substrate 200 used in the substrate processing apparatus 1 of the present embodiments may be of a circular shape when viewed from above. However, instead of the circular shape, the process substrate 200 may be of a shape such as a rectangular shape and a hexagonal shape. For example, when the process substrate 200 is of a circular shape when viewed from above, an outer peripheral length of the process substrate 200 is calculated by multiplying an outer diameter (also simply referred to as a “diameter”) of the process substrate 200 by π. Hereinafter, the outer peripheral length of the process substrate 200, an outer peripheral length of a first cooling substrate 300L described below and an outer peripheral length of a second cooling substrate 300S described below are referred to as an outer diameter (diameter) of the process substrate 200, an outer diameter (diameter) of the first cooling substrate 300L and an outer diameter (diameter) of the second cooling substrate 300S, respectively, to describe a relationship in size.

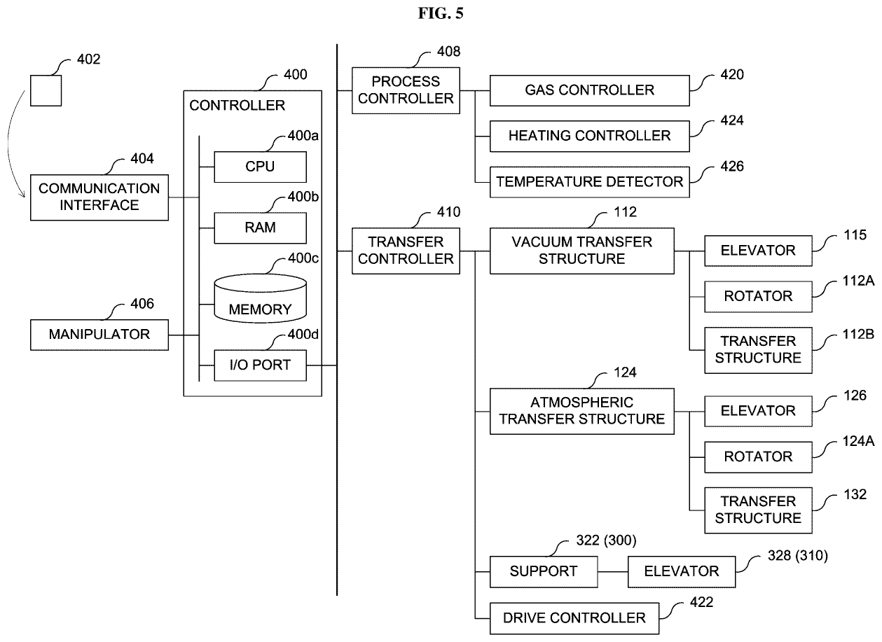

As shown in FIGS. 2 and 5, the first wafer transfer structure 112 includes a rotator (which is a rotating structure) 112A and a transfer structure 112B, and is configured to be elevated and lowered by an elevator 115 serving as an example of an elevating structure while maintaining an airtightness of the first transfer chamber 103.

As shown in FIGS. 1 and 2, a preliminary chamber 122 through which a substrate is loaded and a preliminary chamber 123 through which the substrate is unloaded are connected to two side walls (among six side walls) located at a front side of the housing 101 through gate valves 131 and 127 to be connected to the first transfer chamber 103, respectively. Each of the preliminary chamber 122 and the preliminary chamber 123 is configured as a load lock chamber structure capable of withstanding the negative pressure. In addition, a substrate placement table 140 on which the substrate to be loaded is placed is installed in the preliminary chamber 122, and a substrate placement table 141 on which the substrate to be unloaded is placed is installed in the preliminary chamber 123. In the present embodiments, the term “substrate” corresponds to one among the process substrate 200, the first cooling substrate 300L described below and the second cooling substrate 300S described below. Therefore, the process substrate 200, the first cooling substrate 300L described below and the second cooling substrate 300S can be placed on the substrate placement table 140 or the substrate placement table 141.

A second transfer chamber 121 (which is used under approximately the atmospheric pressure) is connected to front sides of the preliminary chambers 122 and 123 via gate valves 128 and 129.

In the second transfer chamber 121, a second wafer transfer structure (atmospheric transfer structure) 124 is installed as an example of an atmospheric transfer apparatus configured to transfer the process substrate 200. As shown in FIG. 5, the second wafer transfer structure 124 includes a rotator (which is a rotating structure) 124A. The second wafer transfer structure 124 is configured to be elevated and lowered by an elevator 126 (see FIG. 2) serving as an example of an elevating structure installed in the second transfer chamber 121, and further configured to be moved back and forth (that is, reciprocated in a left-right direction) by a linear actuator 132 (see FIG. 2) serving as an example of a transfer structure.

As shown in FIG. 1, an orientation flat aligner (which is an orientation flat aligning structure) 106 is installed on a left side of the second transfer chamber 121. As shown in FIG. 2, a clean air supplier (which is a clean air supply structure) 118 configured to supply clean air is installed at an upper portion of the second transfer chamber 121.

As shown in FIGS. 1 and 2, at a housing 125 of the second transfer chamber 121, a wafer loading/unloading port 134 through which the process substrate 200 is loaded into or unloaded from the second transfer chamber 121, a lid 142 capable of closing the wafer loading/unloading port 134, and a pod opener 108 are provided. The pod opener 108 is provided with a cap opener/closer (which is a cap opening/closing structure) 136 configured to open and close a cap of a pod 100 placed on an I/O stage (input/output stage) 105 and configured to open and close the lid 142 capable of closing the wafer loading/unloading port 134. By opening or closing the cap of the pod 100 placed on the I/O stage 105 and the lid 142 capable of closing the wafer loading/unloading port 134 by using the cap opener/closer 136 of the pod opener 108, the wafer accommodated in the pod 100 can be transferred (loaded) into or transferred (unloaded) out of the second transfer chamber 121. In addition, the pod 100 is supplied to or discharged (unloaded) from the I/O stage 105 by a pod transfer structure (not shown).

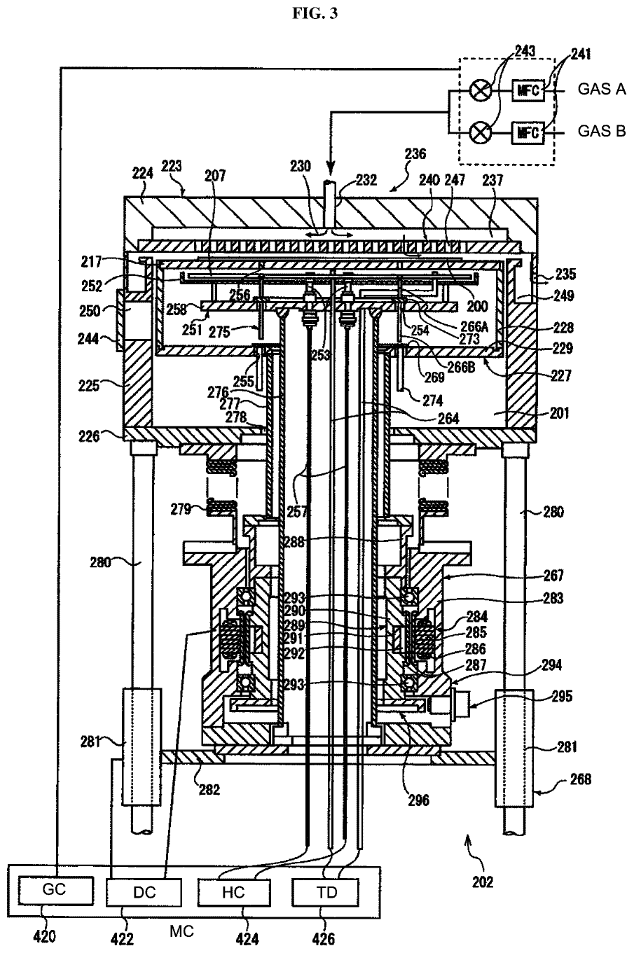

As shown in FIG. 1, a first process furnace 202 (see FIG. 3) configured to perform a desired process on the wafer and a second process furnace 137 configured to perform a desired process on the wafer are adjacently connected to two side walls (among the six side walls) located at a rear side of the housing 101, respectively. The first process furnace 202 and the first transfer chamber 103 are connected to each other via a gate valve 130. Each of the first process furnace 202 and the second process furnace 137 is configured as a cold wall type process furnace.

Further, a cooling substrate cooler (also referred to as a “cooling substrate cooling structure”) 300 and a process substrate cooler (also referred to as a “process substrate cooling structure”) 139 are respectively connected to the remaining two opposing side walls among the six side walls of the housing 101. The cooling substrate cooler 300 is configured to be capable of cooling the first cooling substrate 300L and the second cooling substrate 300S, which will be described later, and the process substrate cooler 139 is configured to be capable of cooling the process substrate 200 (which is processed). A configuration of the cooling substrate cooler 300 will be described later.

In the present embodiments, for example, the housing 101 is of a hexagonal shape when viewed from above. However, the housing 101 is not limited to such a shape. For example, the shape of the housing 101 may vary depending on configurations of the first process furnace 202, the second process furnace 137, the cooling substrate cooler 300, the preliminary chamber 122 and the preliminary chamber 123.

### <Configuration of First Process Furnace 202>

Hereinafter, the configuration of the first process furnace 202 will be described. For the sake of concreteness and clarity, the configuration of the first process furnace 202 of the substrate processing apparatus 1 alone will be described below in detail, but the configuration of the second process furnace 137 is substantially similar to that of the first process furnace 202. As shown in FIG. 3, for example, the first process furnace 202 of the substrate processing apparatus 1 (see FIGS. 1 and 2) is configured as a single wafer type CVD furnace (single wafer and cold wall type CVD furnace), and includes a chamber 223 serving as an example of a process vessel in which a process chamber 201 is provided. The process substrate 200 to be processed is processed in the process chamber 201. The chamber 223 is configured by combining an upper cap 224, a cylindrical cup 225, and a lower cap 226 such that the chamber 223 is of a cylindrical shape with upper and lower end faces closed.

A wafer loading/unloading port 250 (which is opened and closed by a gate valve 244) is formed in the middle of a cylindrical wall of the cylindrical cup 225 of the chamber 223 and is provided with an opening laterally elongated in a horizontal direction. The wafer loading/unloading port 250 is configured such that the process substrate 200 (which is the substrate to be processed) can be loaded into and unloaded from the process chamber 201 by using a wafer transfer structure (not shown). In other words, the process substrate 200 is transferred to the wafer loading/unloading port 250 while being mechanically supported from thereunder by the wafer transfer structure, and then is loaded into or unloaded from the process chamber 201.

An exhaust port 235 connected to an exhaust apparatus (not shown) including a component such as a vacuum pump is formed in an upper portion of a wall surface of the cylindrical cup 225 facing the wafer loading/unloading port 250 such that the exhaust port 235 communicates with the process chamber 201. An inside (an inner side or an inner portion) of the process chamber 201 is evacuated (exhausted) by the exhaust apparatus. In addition, an exhaust buffer space 249 (which communicates with the exhaust port 235) is provided in an upper portion of the cylindrical cup 225. For example, the exhaust buffer space 249 is of an annular shape. The exhaust buffer space 249 is configured such that an evacuation operation (exhaust operation) can be uniformly performed over an entire surface of the process substrate 200.

A shower head 236 through which a process gas is supplied is integrally provided in the upper cap 224 of the chamber 223. That is, a gas supply pipe 232 is inserted into a ceiling wall of the upper cap 224, and a gas supply structure constituted by opening/closing valves 243 and flow controllers (mass flow controllers, MFCs) 241 is connected to the gas supply pipe 232 so as to introduce the process gas such as a process gas “A” (for example, a source gas) and a process gas “B” (for example, a purge gas). A plate 240 of a disk shape is fixed horizontally to a lower surface of the upper cap 224 with a gap from the gas supply pipe 232, and a plurality of gas ejection ports (gas outlets) 247 are provided uniformly over an entire surface of the plate 240 such that a gas such as the process gas is circulated between an upper and lower spaces of the plate 240. A buffer chamber 237 is provided as an inner space defined by an inner surface of the upper cap 224 and an upper surface of the plate 240. The buffer chamber 237 uniformly diffuses the process gas 230 introduced into the gas supply pipe 232 such that the process gas 230 can be uniformly ejected in a shower-like manner through each of the gas ejection ports 247.

An insertion hole 278 of a circular shape is formed in a center portion of the lower cap 226 of the chamber 223, and a support shaft 276 of a circular shape is inserted into the process chamber 201 from thereunder along a center line of the insertion hole 278. The support shaft 276 is elevated and lowered by an elevator (which is an elevating structure) 268 which is configured by using a component such as an air cylinder apparatus.

A heating structure 251 is concentrically arranged and fixed horizontally to an upper end of the support shaft 276, and the heating structure 251 is elevated and lowered by the support shaft 276. In other words, the heating structure 251 is provided with a support plate 258 of a disk shape, and the support plate 258 is fixed concentrically to an upper opening of the support shaft 276. A plurality of electrodes 253 also serving as supports are vertically erected (provided) on an upper surface of the support plate 258, and a heater (heating apparatus) 207 of a disk shape is bridged and fixed between upper ends of the electrodes 253. The heater 207 is divided into a plurality of regions and individually controlled for the plurality of regions. An electrical wiring 257 for the electrodes 253 is inserted through a hollow portion of the support shaft 276. In addition, below the heater 207, a reflecting plate 252 is fixed to the support plate 258. The reflecting plate 252 reflects a heat generated and emitted from the heater 207 toward a susceptor (which is an example of a substrate placement table) 217 so as to achieve efficient heating.

In addition, a radiation thermometer (which is a temperature detection structure) 264 is introduced from a lower end of the support shaft 276. A front end (tip) of the radiation thermometer 264 is installed with a predetermined gap from a back surface of the susceptor 217. For example, the radiation thermometer 264 is configured by combining a quartz rod and an optical fiber. The radiation thermometer 264 is configured to detect a radiant light emitted from the back surface of the susceptor 217 (for example, the back surface corresponding to the divided regions of the heater 207) and to calculate a back surface temperature of the susceptor 217. In addition, the radiation thermometer 264 is further configured to be capable of calculating a temperature of the process substrate 200 based on a previously obtained relationship between the temperature of the process substrate 200 and a temperature of the susceptor 217. Based on the temperature of the susceptor 217 calculated in a manner described above, it is possible to control a heating level (heating state) of the heater 207.

A rotating shaft 277 of a cylindrical shape whose diameter is greater than that of the support shaft 276 is concentrically arranged outside the support shaft 276 in the insertion hole 278 of the lower cap 226. The rotating shaft 277 is inserted into the process chamber 201 from thereunder, and is elevated and lowered together with the support shaft 276 by the elevator 268 which is configured by using the component such as the air cylinder apparatus. A rotating drum 227 is concentrically arranged and fixed horizontally to an upper end of the rotating shaft 277, and the rotating drum 227 is rotated by the rotating shaft 277. In other words, the rotating drum 227 includes a rotating plate (which is a doughnut-shaped flat plate) 229 and a rotating cylinder 228 of a cylindrical shape. An inner peripheral edge of the rotating plate 229 is fixed to an upper end opening of the rotating shaft 277 of the cylindrical shape, and the rotating cylinder 228 is fixed concentrically to an outer peripheral edge of an upper surface of the rotating plate 229. The susceptor 217 (which is an example of a substrate placement table made of a material such as silicon carbide and aluminum nitride) of a disk shape is placed on an upper end of the rotating cylinder 228 of the rotating drum 227 so as to close the upper opening of the rotating cylinder 228.

As shown in FIG. 3, a wafer elevator (which is a wafer elevating structure) 275 is provided on the rotating drum 227. The wafer elevator 275 is configured by providing a plurality of heater side thrust pins 266A, a plurality of heater side thrust pins 266B and a plurality of rotation side thrust pins 274 on each of two lifting rings 269 and 273 of an annular shape. The lifting ring (also referred to as a “rotation side ring”) 269 is arranged concentrically with the support shaft 276 on the rotating plate 229 of the rotating drum 227. For example, the plurality of (for example, three) rotation side thrust pins 274 are arranged at equal intervals in a circumferential direction on a lower surface of the rotation side ring 269 and protrude downward in a vertical direction. Each of the rotation side thrust pins 274 is arranged on the rotating plate 229 on a line concentric with the rotating cylinder 228, and is slidably inserted into each guide hole 255 formed in the vertical direction. A length of each of the rotation side thrust pins 274 is set to be equal to each other such that the rotation side thrust pins 274 can push up the rotation side ring 269 horizontally, and is set to correspond to an amount of thrust from the substrate placement table of the process substrate 200. A lower end of each of the rotation side thrust pins 274 faces a bottom surface of the process chamber 201, that is, an upper surface of the lower cap 226 so as to be freely seated and removed with respect to the bottom surface.

On the support plate 258 of the heating structure 251, another lifting ring of the two lifting rings 269 and 273 of a annular shape, that is, the lifting ring (also referred to as a “heater side ring”) 273 is arranged concentrically with the support shaft 276. For example, the plurality of (for example, three) heater side thrust pins 266B are arranged at equal intervals in a circumferential direction on a lower surface of the heater side ring 273 and protrude downward in the vertical direction. Each of the heater side thrust pins 266B is arranged on the support plate 258 on a line concentric with the support shaft 276, and is slidably inserted into each guide hole 254 formed in the vertical direction. A length of each of the heater side thrust pins 266B is set to be equal to each other such that the heater side thrust pins 266B can push up the heater side ring 273 horizontally. A lower end of each of the heater side thrust pins 266B faces an upper surface of the rotation side ring 269 with an appropriate air gap therebetween. In other words, the heater side thrust pins 266B are designed not to interfere with the rotation side ring 269 when the rotating drum 227 rotates.

For example, the plurality of (for example, three) heater side thrust pins 266A are arranged at equal intervals in a circumferential direction on an upper surface of the heater side ring 273 and protrude upward in the vertical direction. In addition, upper ends of the heater side thrust pins 266A face insertion holes 256 of the susceptor 217 and the heater 207. Lengths of the heater side thrust pins 266A are set to be equal to each other such that the heater side thrust pins 266A can be inserted into the insertion holes 256 of the susceptor 217 and the heater 207 from thereunder to horizontally elevate the process substrate 200 (which is placed on the susceptor 217) from the susceptor 217. In addition, the lengths of the heater side thrust pins 266A are set such that the upper ends of the heater side thrust pins 266A do not protrude from an upper surface of the heater 207 when the heater side ring 273 is seated on the support plate 258. In other words, the heater side thrust pins 266A are designed not to interfere with the susceptor 217 when the rotating drum 227 rotates, and not to interfere with a heating by the heater 207.

As shown in FIG. 3, the chamber 223 is supported horizontally by a plurality of support columns 280. A plurality of elevating blocks 281 are fitted into the support columns 280, respectively, such that the elevating blocks 281 can be elevated and lowered freely. An elevating table 282 is installed between the elevating blocks 281. The elevating table 282 is elevated and lowered by an elevating driver (which is an elevating driving structure) (not shown) which is configured by using a component such as an air cylinder apparatus. A substrate placement table rotator (which is a substrate placement table rotating structure) 267 is installed on the elevating table 282. Further, a bellows 279 is interposed between the substrate placement table rotator 267 and the chamber 223 so as to airtightly (hermetically) seal an outside (outer portion) of the rotating shaft 277.

A brushless DC motor is used for the substrate placement table rotator 267 installed on the elevating table 282, and an output shaft (motor shaft) thereof is provided as a hollow shaft and configured as the rotating shaft 277. The substrate placement table rotator 267 includes a housing 283. The housing 283 is installed vertically upward on the elevating table 282. A stator 284 made of an electromagnet (coil) is fixed to an inner peripheral surface of the housing 283. That is, the stator 284 is configured by winding a coil wire (enamel-coated copper wire) 286 around an iron core 285. A lead wire (not shown) is electrically connected to the coil wire 286 by inserting the lead wire through an insertion hole (not shown) formed in a side wall of the housing 283. The stator 284 forms a rotating magnetic field by an electric power supplied from a driver (not shown) of the brushless DC motor to the coil wire 286 through the lead wire.

A rotor 289 is arranged concentrically at an inner side of the stator 284 with an air gap therebetween, and the rotor 289 is rotatably supported by the housing 283 via ball bearings (that is, an upper ball bearing and a lower ball bearing) 293. In other words, the rotor 289 includes: a main structure (main body) 290 of a cylindrical shape; an iron core 291; and a plurality of permanent magnets 292. Further, the rotating shaft 277 is fixed to the main structure 290 by a bracket 288 so as to rotate integrally with the main structure 290. The iron core 291 is fitted into and fixed to the main structure 290, and the plurality of permanent magnets 292 are fixed to an outer periphery of the iron core 291 at equal intervals in a circumferential direction. A plurality of magnetic poles arranged in a ring shape are provided by the iron core 291 and the plurality of permanent magnets 292. The rotating magnetic field formed (provided) by the stator 284 cuts the magnetic field of the plurality of magnetic poles (permanent magnets 292). Thereby, the rotor 289 rotates.

The ball bearings (that is, the upper ball bearing and the lower ball bearing) 293 are provided at upper and lower ends of the main structure 290 of the rotor 289, respectively, and an appropriate gap is set between the ball bearings (that is, the upper ball bearing and the lower ball bearing) 293 to absorb a thermal expansion of the main structure 290. The gap between the ball bearings 293 is set within a range from 5 μm to 50 μm (that is, 5 μm or more and 50 μm or less) so as to absorb the thermal expansion of the main structure 290 and to minimize rattling. In addition, the gap between the ball bearings 293 may refer to a gap which is provided on an opposite side when balls of the ball bearings 293 are moved to either an outer race or an inner race on one side.

Further, in the present specification, a notation of a numerical range such as “from 5 μm to 50 μm” means that a lower limit and an upper limit are included in the numerical range. Therefore, for example, the numerical range “from 5 μm to 50 μm” means a range equal to or higher 5 μm and equal to or less than 50 μm. The same also applies to other numerical ranges described in the present specification.

For example, on the opposing surfaces of the stator 284 and the rotor 289, covers (which are outer and inner enclosure structures constituting a double cylindrical wall) 287 are provided to face each other, and are fixed to the inner peripheral surface of the housing 283 and an outer peripheral surface of the main structure 290, respectively. A predetermined air gap (interval) is set between each of the covers 287. Each of the covers 287 is made of stainless steel (which is a non-magnetic material), and is of a cylindrical shape with a very thin cylindrical wall. At upper and lower open ends of the covers 287 of the cylindrical shape, the covers 287 are securely and uniformly fixed to the housing 283 and the main structure 290 over an entire circumference by using an electron beam welding. Since each of the covers 287 is made of stainless steel (non-magnetic material) with the very thin cylindrical wall, it is possible to prevent not only a diffusion of a magnetic flux and a decrease in a motor efficiency but also a corrosion of the coil wire 286 of the stator 284 and a corrosion of the permanent magnets 292 of the rotor 289. Thereby, it is possible to reliably prevent a contamination of the inside of the process chamber 201 by a component such as the coil wire 286. The covers 287 are configured to surround the stator 284 in an airtightly sealed manner such that the stator 284 is completely isolated from the inside of the process chamber 201 (which is in a vacuum atmosphere).

Further, a magnetic rotary encoder 294 is provided at the substrate placement table rotator 267. That is, the magnetic rotary encoder 294 includes a detectable ring 296 serving as a detectable structure containing a magnetic material. The detectable ring 296 is of a circular ring shape constituted by using a magnetic material such as iron. A large number (plurality number) of teeth serving as a detectable portion are arranged in a ring shape on an outer periphery of the detectable ring 296.

A magnetic sensor 295 is provided at a position of the housing 283 to face the detectable ring 296. The magnetic sensor 295 is configured to detect each of the teeth serving as the detectable portion of the detectable ring 296. A gap (sensor gap) between a front end face of the magnetic sensor 295 and an outer peripheral surface of the detectable ring 296 is set within a range from 0.06 mm to 0.17 mm (0.06 mm or more and 0.17 mm or less). The magnetic sensor 295 detects a change in the magnetic flux at the opposing position associated with a rotation of the detectable ring 296 using a magnetic resistance element. A detection result of the magnetic sensor 295 is sent to a drive controller 422 (see FIGS. 3 and 5) described later, and is used to recognize a position of the susceptor 217 and also to control an amount of a rotation of the susceptor 217. The drive controller 422 is configured to control the brushless DC motor (the substrate placement table rotator 267).

Further, a pressure (inner pressure) of the process chamber 201 is monitored using a pressure gauge (not shown) (which is connected to a controller 400 described later). For example, when the process substrate 200 is processed with the process gases A and B such as the source gas and the purge gas, the inner pressure of the process chamber 201 is maintained at a predetermined pressure by controlling the MFCs 241 and the exhaust apparatus (not shown).

### <Controller 400>

As shown in FIG. 5, the substrate processing apparatus 1 according to the present embodiments includes the controller 400 configured to control components of the substrate processing apparatus 1. The controller 400 includes at least an arithmetic processor 400a such as a CPU (Central Processing Unit) 400a, a temporary memory 400b such as a RAM (Random Access Memory) 400b, a memory 400c and an I/O port (input/output port) 400d. The controller 400 is connected to the components of the substrate processing apparatus 1 via the I/O port 400d, calls a program or a recipe from the memory 400c in accordance with an instruction from an externally connected apparatus (not shown) via a manipulator 406 or a communication interface 404, and controls operations of the components of the substrate processing apparatus 1 in accordance with the contents of the instruction.

For example, the controller 400 may be embodied by a dedicated computer or by a general-purpose computer. According to the present embodiments, for example, the controller 400 may be embodied by preparing an external memory 402 (which is computer-readable) storing the program mentioned above and by installing the program onto the general-purpose computer using the external memory 402. For example, the external memory 402 may include a magnetic tape, a magnetic disk such as a flexible disk and a hard disk, an optical disk such as a CD and a DVD, a magneto-optical disk such as an MO and a semiconductor memory such as a USB memory (USB flash drive) and a memory card.

In addition, a method of providing the program to the computer is not limited to that using the external memory 402. For example, the program may be supplied to the computer (general-purpose computer) using a communication structure such as the Internet and a dedicated line. For example, the program may be provided to the computer without using the external memory 402 by receiving information (that is, the program) via the communication interface 404. In addition, a user can input the instruction to the controller 400 using the manipulator 406 such as a keyboard and a touch panel.

According to the present embodiments, the memory 400c or the external memory 402 may be embodied by a non-transitory computer readable recording medium. Hereafter, the memory 400c and the external memory 402 may be collectively or individually referred to as a “recording medium”. Thus, in the present specification, the term “recording medium” may refer to the memory 400c alone, may refer to the external memory 402 alone, or may refer to both of the memory 400c and the external memory 402.

As shown in FIG. 5, a process controller 408 and a transfer controller 410 are connected to the controller 400 via the I/O port 400d.

As shown in FIG. 5, a gas controller (“GC” shown in FIG. 3) 420, a heating controller (“HC” shown in FIG. 3) 424 and a temperature detector (“TD” shown in FIG. 3) 426 are connected to the process controller 408. As shown in FIG. 3, the gas controller 420, the drive controller (“DC” shown in FIG. 3) 422, the heating controller 424 and the temperature detector 426 are related to a control of each component of the first process furnace 202. Thus, the gas controller 420, the drive controller 422, the heating controller 424 and the temperature detector 426 may be collectively referred to as a “main controller” (“MC” shown in FIG. 3).

The gas controller 420 shown in FIG. 5 includes the MFCs 241, the opening/closing valves 243, the exhaust apparatus (not shown) connected to the process chamber 201, the pressure gauge (not shown) configured to measure the inner pressure of the process chamber 201 and the like. The drive controller 422 includes the substrate placement table rotator (which is a rotator) 267, the elevator (elevating structure) 268 and the like. The heating controller 424 includes the heater (heating apparatus) 207 and the like. The temperature detector 426 includes the radiation thermometer (temperature detection structure) 264 and the like.

For example, the first wafer transfer structure (vacuum transfer structure) 112, the second wafer transfer structure (atmospheric transfer structure) 124, an elevator (elevating structure) 328 capable of elevating and lowering a support (which is a support structure) 322 of the cooling substrate cooler 300 described later, a gate valve 310 and the like are connected to the transfer controller 410. The transfer controller 410 is configured to be capable of controlling the first wafer transfer structure (vacuum transfer structure) 112, the second wafer transfer structure (atmospheric transfer structure) 124, the elevator 328 and the like.

### <Configuration of Cooling Substrate Cooler 300>

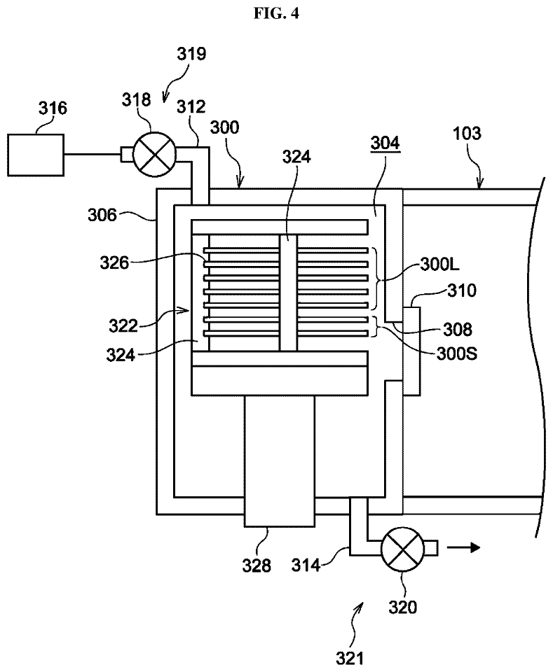

As shown in FIG. 4, the cooling substrate cooler 300 includes a housing 306 of a box shape. In the housing 306, an accommodation chamber (which is a space where the first cooling substrate 300L and the second cooling substrate 300S to be cooled are arranged and cooled) 304 is provided.

As shown in FIGS. 1 and 4, the cooling substrate cooler 300 is provided adjacent to the first transfer chamber 103. A cooling substrate loading/unloading port 308 is provided on a side portion of the housing 306. The first cooling substrate 300L and the second cooling substrate 300S are loaded into and unloaded out of the first transfer chamber 103 through the cooling substrate loading/unloading port 308. In addition, the gate valve 310 capable of being opened and closed is provided at the cooling substrate loading/unloading port 308. An opening and closing operation of the gate valve 310 is controlled by the controller 400 shown in FIG. 5. Specifications of the first cooling substrate 300L and the second cooling substrate 300S will be described later.

As shown in FIG. 4, a supply pipe 312 through which a cooling gas is supplied into the accommodation chamber 304 and an exhaust pipe 314 through which the gas (that is, the cooling gas) is exhausted from the accommodation chamber 304 are connected to the housing 306.

For example, a cooling gas supplier (which is a cooling gas supply structure) 316 including a component such as a gas tank capable of supplying the cooling gas may be provided at an upstream side of the supply pipe 312. A supply valve 318 is provided in the middle of the supply pipe 312. An opening and closing operation of the supply valve 318 is controlled by the controller 400 shown in FIG. 5. For example, a supply system 319 is constituted by the supply pipe 312 and the supply valve 318. The supply system 319 may further include the cooling gas supplier 316. In addition, the supply system 319 may be or may not be a component constituting the substrate processing apparatus 1 of the present disclosure. In the present embodiments, in order to increase a cooling rate of the first cooling substrate 300L and the second cooling substrate 300S, the cooling gas is supplied into the accommodation chamber 304 to forcibly cool the first cooling substrate 300L and the second cooling substrate 300S. However, a natural air cooling may be performed inside the accommodation chamber 304 without using the cooling gas. In addition, instead of providing the housing (which is of a sealed box shape) 306 to accommodate the first cooling substrate 300L and the second cooling substrate 300S, the first cooling substrate 300L and the second cooling substrate 300S may be naturally cooled in a space open to the atmosphere. For example, the term “natural air cooling” refers to a windless cooling where there is no forced wind (air, gas other than the air, etc.) from outside being used.

As the cooling gas, for example, a gas such as helium (He) gas, argon (Ar) gas may be used. However, another gas other than the He gas and the Ar gas may also be used as the cooling gas. A temperature of the cooling gas supplied into the housing 306 is set to be lower than the temperature of the susceptor 217 which has become high after a film forming process is completed. For example, the temperature of the cooling gas is preferably set to a room temperature (for example, 25° C.) or lower.

An exhaust valve 320 is provided in the middle of the exhaust pipe 314. An opening and closing operation of the exhaust valve 320 is also controlled by the controller 400. For example, an exhaust system 321 is constituted by the exhaust pipe 314 and the exhaust valve 320. The exhaust system 321 may further include a vacuum pump (not shown) provided at a downstream side of the exhaust pipe 314. In addition, the exhaust system 321 may be or may not be a component constituting the substrate processing apparatus 1 of the present disclosure.

Inside the housing 306, the support 322 capable of supporting a plurality of first cooling substrates including the first cooling substrate 300L and a plurality of second cooling substrates including the second cooling substrate 300S in a multistage manner in the vertical direction is arranged. Hereinafter, the plurality of first cooling substrates including the first cooling substrate 300L may also be simply referred to as “first cooling substrates 300L”, and the plurality of second cooling substrates including the second cooling substrate 300S may also be simply referred to as “second cooling substrates 300S”. The support 322 includes a plurality of support columns 324, and is configured to support the first cooling substrates 300L and the second cooling substrates 300S by inserting end portions of the first cooling substrates 300L and the second cooling substrates 300S into grooves 326 provided in the support columns 324. Further, the cooling substrate cooler 300 in FIG. 4 is schematically illustrated, and the number of the first cooling substrates 300L and the second cooling substrates 300S supported by the support 322 is not limited to the number shown in FIG. 4.

The elevator 328 configured to elevate and lower the support 322 in the vertical direction is provided at the housing 306.

When the first cooling substrate 300L and the second cooling substrate 300S are moved in and out between the cooling substrate cooler 300 and the first transfer chamber 103, the gate valve 310 is opened, and when the first cooling substrate 300L and the second cooling substrate 300S accommodated in the housing 306 are cooled, the gate valve 310 is closed to supply the cooling gas into the housing 306. The gate valve 310 is also closed when an inside (inner atmosphere) of the first transfer chamber 103 is evacuated (exhausted) to a vacuum state.

### <Specifications of Cooling Substrates>

In the substrate processing apparatus 1 of the present embodiments, for example, the first cooling substrate 300L (whose diameter is smaller than that of the process substrate 200 and smaller than an inner diameter of a film 32 described later) and the second cooling substrate 300S (whose diameter is smaller than that of the first cooling substrate 300L) are prepared. As shown in FIG. 4, the first cooling substrate 300L and the second cooling substrate 300S are supported by the support 322 of the cooling substrate cooler 300.

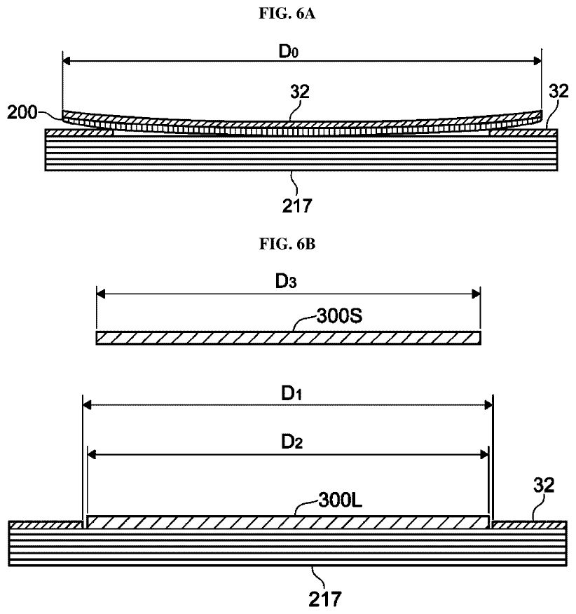

FIG. 6A is a diagram schematically illustrating the process substrate 200 placed on the susceptor 217 and provided with the film 32 formed thereon, and FIG. 6B is a diagram schematically illustrating the susceptor 217, the film 32, the first cooling substrate 300L and the second cooling substrate 300S. In examples shown in FIG. 6A and FIG. 6B, when the diameter of the process substrate 200 is D₀, the inner diameter of the film 32 (of an annular shape) formed on the susceptor 217 is D₁, the outer diameter of the first cooling substrate 300L is D₂ and the outer diameter of the second cooling substrate 300S is D₃, there is a relationship of “D₀>D₁>D₂>D₃”, that is, D₀ is greater than D₁, D₁ is greater than D₂, and D₂ is greater than D₃. In addition, when the process substrate 200, the first cooling substrate 300L and the second cooling substrate 300S of the present embodiments are described in terms of a size relationship of areas when viewed from above, an area of the process substrate 200 is greater than an area of the first cooling substrate 300L, and the area of the first cooling substrate 300L is greater than an area of the second cooling substrate 300S.

For example, the outer diameters of the first cooling substrate 300L and the second cooling substrate 300S can be set within a range from 90% to 99% (that is, 90% or more and 99% or less) of the outer diameter of the process substrate 200. Therefore, for example, when the outer diameter of the process substrate 200 is set to 300 mm, the outer diameter of the first cooling substrate 300L is set to 297 mm, and the outer diameter of the second cooling substrate 300S is set to 270 mm.

In the substrate processing apparatus 1 of the present embodiments, for example, the diameter Do of the process substrate 200 is set to 300 mm, the diameter D₂ of the first cooling substrate 300L is set to 290 mm, and the diameter D₃ of the second cooling substrate 300S is set to 280 mm.

In addition, the inner diameter D₁ of the film 32 formed on the susceptor 217 may be obtained by performing a test (experiment) in advance and measuring the inner diameter of the film 32 actually formed on the susceptor 217 after performing the film forming process on the process substrate 200. It is preferable to determine the diameter D₂ of the first cooling substrate 300L and the diameter D₃ of the second cooling substrate 300S based on a minimum value of the inner diameter D₁ of the film 32. The minimum value may be obtained by performing the film forming process a plurality of times, and the diameter D₂ of the first cooling substrate 300L and the diameter D₃ of the second cooling substrate 300S may be determined so as to be equal to or smaller than the minimum value.

When the outer diameter D₂ of the first cooling substrate 300L and the outer diameter D₃ of the second cooling substrate 300S are 90% or less of the outer diameter Do of the process substrate 200, a cooling efficiency may decrease and a cleaning gas may be supplied to a surface (upper surface) of the susceptor 217 exposed between the inner diameter (inner edge) of the film 32 and the outer diameter (outer edge) of the first cooling substrate 300L or the second cooling substrate 300S during a cleaning process described later. Thereby, the surface of the susceptor 217 may be affected.

In addition, when the outer diameter D₂ of the first cooling substrate 300L and the outer diameter D₃ of the second cooling substrate 300S are 99% or more of the outer diameter Do of the process substrate 200, a peripheral portion of the substrate may be placed on the film 32 of the annular shape, and a space may be created between the susceptor 217 and a central portion of the first cooling substrate 300L or the second cooling substrate 300S. As a result, the first cooling substrate 300L or the second cooling substrate 300S may not come into close contact with the susceptor 217, and the cooling efficiency of the susceptor 217 may decrease. Further, in the cleaning process, since the peripheral portion of the substrate may be placed on the film 32, a part of the film 32 may be covered by the peripheral portion of the substrate, and the cleaning process for the film 32 may not be performed correctly. The cleaning process for the film 32 will be described later in detail.

The first cooling substrate 300L and the second cooling substrate 300S (which are used to cool the susceptor 217) may be wafers normally used in a manufacturing process of the semiconductor device as long as the outer peripheral lengths (outer diameters) thereof are shorter than the outer peripheral length (outer diameter) of the process substrate 200, or may be dedicated wafers designed to be suitable for performing a method of the present disclosure.

Similar to the process substrate 200, each of the first cooling substrate 300L and the second cooling substrate 300S used in the substrate processing apparatus 1 of the present embodiments is of a circular shape when viewed from above, and surfaces (front and back surfaces) thereof are flat (smooth and without convex or concave portion).

The first cooling substrate 300L and the second cooling substrate 300S are preferably made of a material whose thermal conductivity is high and less likely to generate particles. For example, a metal material such as aluminum, a carbon material, a ceramic material such as SiC, AlN and Al₂O₃ may be used. In addition, the first cooling substrate 300L and the second cooling substrate 300S may be made of the same material as the wafers normally used in the manufacturing process of the semiconductor device.

Thicknesses of the first cooling substrate 300L and the second cooling substrate 300S may be the same as that of the process substrate 200, may be thicker than that of the process substrate 200, or may be thinner than that of the process substrate 200.

### <Processing by Substrate Processing Apparatus 1>

Hereinafter, a processing process by the substrate processing apparatus 1 shown in FIGS. 1 to 3 will be described. First, the film forming process on the process substrate 200 will be described. As an example, in a state where a plurality of (for example, 25) process substrates (which are unprocessed) including the process substrate 200 are accommodated in the pod 100, the pod 100 is transferred by an in-process transfer apparatus (not shown) to the substrate processing apparatus 1 where the processing process is performed. Hereinafter, the plurality of process substrates including the process substrate 200 may also be simply referred to as “process substrates 200”. As shown in FIGS. 1 and 2, the pod 100 (which is transferred) is received from the in-process transfer apparatus and placed on the I/O stage 105. The lid 142 configured to open and close the wafer loading/unloading port 134 and the cap of the pod 100 are removed by the cap opener/closer 136, and a wafer entrance of the pod 100 is opened.

After the pod 100 is opened by the pod opener 108, the second wafer transfer structure 124 installed in the second transfer chamber 121 picks up the process substrate 200 from the pod 100, transfers (loads) the process substrate 200 into the preliminary chamber 122, and transfers the process substrate 200 to the substrate placement table 140. During such a transfer operation, the gate valve 131 provided adjacent to the first transfer chamber 103 is closed, and the negative pressure in the first transfer chamber 103 is maintained. After the transfer operation for the process substrates 200 to the substrate placement table 140 is completed, the gate valve 128 is closed, and the preliminary chamber 122 is evacuated (exhausted) to the negative pressure by the exhaust apparatus (not shown).

After a pressure (inner pressure) of the preliminary chamber 122 is reduced to a preset pressure value, the gate valves 131 and 130 are opened. Thereby, the preliminary chamber 122, the first transfer chamber 103 and the first process furnace 202 communicate with one another. Subsequently, the first wafer transfer structure 112 in the first transfer chamber 103 picks up the process substrate 200 from the substrate placement table 140 and loads the process substrate 200 onto the susceptor 217 in the first process furnace 202. Then, the process gas is supplied into the first process furnace 202, and the desired process is performed on the process substrate 200. The process in the first process furnace 202 will be described below in detail.

After the processing is completed in the first process furnace 202, the process substrate 200 (which is processed) is transferred to the first transfer chamber 103 by the first wafer transfer structure 112 in the first transfer chamber 103. Subsequently, the first wafer transfer structure 112 transfers the process substrate 200 (which is transferred out of the first process furnace 202) into the process substrate cooler 139 where the process substrate 200 (which is processed) is cooled.

After the process substrate 200 is transferred to the process substrate cooler 139, the first wafer transfer structure 112 transfers the process substrate 200 (which has been prepared in advance on the substrate placement table 140 in the preliminary chamber 122) to the first process furnace 202 in a manner described above. In addition, the process gas is supplied into the first process furnace 202, and the desired process is performed on the process substrate 200.

When a cooling time (which is set in advance) has elapsed in the process substrate cooler 139, the process substrate 200 (which is cooled) is transferred from the process substrate cooler 139 to the first transfer chamber 103 by the first wafer transfer structure 112.

After the process substrate 200 (which is cooled) is transferred from the process substrate cooler 139 to the first transfer chamber 103, the gate valve 127 is opened. Subsequently, the first wafer transfer structure 112 transfers the process substrate 200 (which is transferred from the process substrate cooler 139) to the preliminary chamber 123 and places the process substrate 200 on the substrate placement table 141. Then, the preliminary chamber 123 is closed by the gate valve 127.

After the preliminary chamber 123 is closed by the gate valve 127, the inner pressure of the preliminary chamber 123 is returned to approximately the atmospheric pressure by the inert gas. After the inner pressure of the preliminary chamber 123 is returned to approximately the atmospheric pressure, the gate valve 129 is opened, and the lid 142 closing the wafer loading/unloading port 134 corresponding to the preliminary chamber 123 of the second transfer chamber 121 and the cap of the pod 100 (which is empty) placed on the I/O stage 105 are opened by the pod opener 108. Subsequently, the second wafer transfer structure 124 in the second transfer chamber 121 picks up the process substrate 200 from the substrate placement table 141 and transfers the process substrate 200 out of the second transfer chamber 121. Then, the second wafer transfer structure 124 stores the process substrate 200 in the pod 100 through the wafer loading/unloading port 134 of the second transfer chamber 121. By repeatedly performing such an operation described above, the wafers (that is, the process substrates 200) are processed sequentially by the substrate processing apparatus 1.

After the process substrates 200 (for example, 25 process substrates 200 which are processed) are stored in the pod 100, the lid 142 closing the wafer loading/unloading port 134 and the cap of the pod 100 are closed by the pod opener 108. When the pod 100 is closed, the pod 100 is transferred from the I/O stage 105 to a subsequent processing by the in-process transfer apparatus. The present embodiments are described by way of a specific example in which the first process furnace 202 and the process substrate cooler 139 are used. However, when the second process furnace 137 is used, the wafers (that is, the process substrates 200) are processed in a substantially similar manner.

### <Processing in First Process Furnace 202>

Hereinafter, a processing in the first process furnace 202 (see FIG. 3) of the substrate processing apparatus 1 will be further described in detail. For the sake of concreteness and clarity, the processing in the first process furnace 202 will be described below in detail, but a processing in the other process furnace (that is, the second process furnace 137) of the substrate processing apparatus 1 is substantially similar to that in the first process furnace 202. When the process substrate 200 is loaded into or unloaded out of the first process furnace 202, the rotating drum 227 and the heating structure 251 are lowered to their lowest positions by the rotating shaft 277 and the support shaft 276. Then, the lower end of each of the rotation side thrust pins 274 of the wafer elevator 275 abuts against the bottom surface of the process chamber 201 (the upper surface of the lower cap 226), and the rotation side ring 269 is elevated relative to the rotating drum 227 and the heating structure 251. The rotation side ring 269 pushes up the heater side thrust pins 266B of the heater side ring 273. Thereby, the heater side ring 273 is elevated. When the heater side ring 273 is elevated, the plurality of (for example, three) heater side thrust pins 266A standing on the heater side ring 273 are inserted into the insertion holes 256 of the heater 207 and the susceptor 217, and support the process substrate 200 placed on the upper surface of the susceptor 217 from thereunder. Thereby, the process substrate 200 is elevated upward from the susceptor 217.

After the wafer elevator 275 has elevated the process substrate 200 from the upper surface of the susceptor 217, an insertion space is provided below the process substrate 200 (between the lower surface of the process substrate 200 and the upper surface of the susceptor 217). Thus, tweezers (which are substrate holding plates provided on the wafer transfer structure (not shown)) are inserted into the insertion space below the process substrate 200 through the wafer loading/unloading port 250. The tweezers inserted below the process substrate 200 is elevated to transfer and receive the process substrate 200. The tweezers that have received the process substrate 200 retreat through the wafer loading/unloading port 250 and unload the process substrate 200 from the process chamber 201. After unloading the process substrate 200 by using the tweezers, the wafer transfer structure then transfers the process substrate 200 to a predetermined storage location such as an empty wafer cassette outside the process chamber 201.

Subsequently, the wafer transfer structure receives the process substrate 200 (which is subjected to a subsequent film forming process) from a predetermined storage location such as a wafer cassette (which is not empty) by using the tweezers, and transfers the process substrate 200 into the process chamber 201 through the wafer loading/unloading port 250. The tweezers transfer the process substrate 200 to a predetermined position above the susceptor 217 where a center of the process substrate 200 coincides with a center of the susceptor 217. After the process substrate 200 is transferred to the predetermined position, the tweezers are lowered slightly and transfer the process substrate 200 to the susceptor 217. After delivering the process substrate 200 to the wafer elevator 275, the tweezers exit the process chamber 201 through the wafer loading/unloading port 250. After the tweezers have exited the process chamber 201, the wafer loading/unloading port 250 is closed by the gate valve (partition valve) 244.

After the gate valve 244 is closed, the rotating drum 227 and the heating structure 251 are elevated with respect to the process chamber 201 by the elevating table 282 via the rotating shaft 277 and the support shaft 276. As the rotating drum 227 and the heating structure 251 are elevated, the heater side thrust pins 266A, the heater side thrust pins 266B and the rotation side thrust pins 274 are lowered relative to the rotating drum 227 and the heating structure 251, and the process substrate 200 is completely transferred onto the susceptor 217, as shown in FIG. 3. The rotating shaft 277 and the support shaft 276 are stopped at a position where the upper ends of the heater side thrust pins 266A are at a height close to a lower surface of the heater 207.

In addition, the process chamber 201 is exhausted by the exhaust apparatus (not shown) connected to the exhaust port 235. When exhausting the process chamber 201, the vacuum atmosphere in the process chamber 201 and an external atmospheric pressure atmosphere are isolated by the bellows 279.

Subsequently, the rotating drum 227 is rotated by the substrate placement table rotator 267 via the rotating shaft 277. In other words, when the substrate placement table rotator 267 is operated, the rotating magnetic field of the stator 284 cuts the magnetic field of the plurality of magnetic poles. Thereby, the rotor 289 is rotated. In addition, the rotating drum 227 is rotated by the rotating shaft 277 fixed to the rotor 289. In such a state, a rotational position of the rotor 289 is timely detected by the magnetic rotary encoder 294 installed in the substrate placement table rotator 267 and transmitted to the drive controller 422. Therefore, a rotation speed and other parameters are controlled based on such a signal transmitted to the drive controller 422.

While the rotating drum 227 is rotated, the rotation side thrust pins 274 are removed from the bottom surface of the process chamber 201, and the heater side thrust pins 266B are removed from the rotation side ring 269. As a result, a rotation of the rotating drum 227 is not impeded (or interfered) by the wafer elevator 275, and the heating structure 251 remains stopped. In other words, in the wafer elevator 275, the rotation side ring 269 and the rotation side thrust pins 274 rotate together with the rotating drum 227, and the heater side ring 273 and the heater side thrust pins 266A are stopped together with the heating structure 251.

When the temperature of the process substrate 200 is elevated to a process temperature and an exhaust amount (exhaust rate) of the exhaust port 235 and a rotational operation of the rotating drum 227 are stabilized, the process gas 230 is introduced into the gas supply pipe 232, as shown by solid arrows in FIG. 3. The process gas 230 introduced into the gas supply pipe 232 flows into the buffer chamber 237 which functions as a gas dispersion space, and then diffuses radially outward in a radial direction. That is, the process gas 230 flows in a roughly uniform manner, and is ejected in a shower-like manner toward the process substrate 200 through each of the gas ejection ports 247 of the plate 240. The process gas 230 ejected in the shower-like manner through each of the gas ejection ports 247 is sucked into the exhaust port 235 via the exhaust buffer space 249, and then is exhausted.

In the present embodiments, the term “process temperature” may refer to the temperature of the process substrate 200 or a temperature (inner temperature) of the process chamber 201, and the term “process time” may refer to a time duration during which a process related thereto continues. The same also applies to the following description.

In such a state, the process substrate 200 on the susceptor 217 supported by the rotating drum 227 is rotated. Therefore, the process gas 230 ejected in the shower-like manner through each of the gas ejection ports 247 uniformly comes into contact with the entire surface of the process substrate 200. Because the process gas 230 uniformly comes into contact with the entire surface of the process substrate 200, it is possible to uniformly form a CVD film (that is, the film 32 shown in FIG. 6A) on the process substrate 200 by the process gas 230. That is, it is possible to uniformize a thickness distribution and a quality distribution of the film 32 over the entire surface of the process substrate 200.

In addition, the heating structure 251 is supported by the support shaft 276 and is not rotated. Therefore, a temperature distribution of the process substrate 200 heated by the heating structure 251 while being rotated by the rotating drum 227 is uniformly controlled over the entire surface thereof. In a manner described above, since the temperature distribution of the process substrate 200 is uniformly controlled over the entire surface thereof, the thickness distribution and the quality distribution of the CVD film (that is, the film 32) formed on the process substrate 200 by a thermochemical reaction can be uniformly controlled over the entire surface of the process substrate 200.

When the process time (which is set in advance) has elapsed, an operation of the substrate placement table rotator 267 is stopped. In such a state, since a rotational position of the susceptor 217 (that is, the rotational position of the rotor 289) is timely monitored by the magnetic rotary encoder 294 installed on the substrate placement table rotator 267, the susceptor 217 is stopped accurately at a preset rotational position. In other words, the heater side thrust pins 266A and the insertion holes 256 of the heater 207 and the susceptor 217 are aligned accurately and with a good reproducibility.

When the operation of the substrate placement table rotator 267 is stopped, as described above, the rotating drum 227 and the heating structure 251 are lowered to a loading/unloading position by the elevating table 282 via the rotating shaft 277 and the support shaft 276. In addition, as described above, when lowering the rotating drum 227 and the heating structure 251, the process substrate 200 is elevated upward from the susceptor 217 by an action of the wafer elevator 275. In such a state, since the heater side thrust pins 266A and the insertion holes 256 of the heater 207 and susceptor 217 are aligned accurately and with the good reproducibility, there is no thrust error in which the heater side thrust pins 266A push up the susceptor 217 and the heater 207. Thereafter, such a process described above is repeatedly performed to form the CVD film on a subsequent process substrate 200. The process substrate 200 on which the CVD film of a predetermined thickness is formed is then unloaded from the process chamber 201.

However, when the process substrate 200 is placed on the susceptor 217, as shown in FIG. 6A, a gap may be provided between the susceptor 217 and an outer periphery of the process substrate 200 due to a warping of the process substrate 200. In such a case, the film 32 (which is unintended) may be formed not only on a radially outer portion of the process substrate 200, but also in a portion between the process substrate 200 and the susceptor 217. The film 32 (which is unintended) can be removed by performing the cleaning process described below after the film forming process.

### <Cleaning Process>

Hereinafter, the cleaning process of the susceptor 217 in the present embodiments will be described. For the sake of specificity and clarity, the cleaning process of the susceptor 217 in the first process furnace 202 (FIG. 3) will be described below in detail, but the cleaning process of the susceptor 217 in the other process furnace (that is, the second process furnace 137) is substantially similar to that in the first process furnace 202.

The cleaning process in the present embodiments is performed at a temperature lower than that of the film forming process. First, an overview of the cleaning process will be described. In the cleaning process, a cooling process for the susceptor 217 is performed such that the temperature of the susceptor 217 is lowered to a cleaning temperature, and when the exhaust amount (exhaust rate) of the exhaust port 235 and the rotational operation of the rotating drum 227 are stabilized, the cleaning gas is introduced into the gas supply pipe 232, as shown by the solid arrows in FIG. 3.

The cleaning gas introduced into the gas supply pipe 232 flows into the buffer chamber 237 which functions as the gas dispersion space, and then diffuses radially outward in the radial direction. That is, the cleaning gas flows in a roughly uniform manner, and is ejected in a shower-like manner toward the susceptor 217 through each of the gas ejection ports 247 of the plate 240. The cleaning gas ejected in the shower-like manner through each of the gas ejection ports 247 passes through a space above the susceptor 217. Then, the cleaning gas is sucked into the exhaust port 235 via the exhaust buffer space 249, and then is exhausted.

In such a state, the susceptor 217 supported by the rotating drum 227 is rotated. Therefore, the cleaning gas ejected in the shower-like manner through each of the gas ejection ports 247 uniformly comes into contact with the film 32 on the susceptor 217. Thereby, the film 32 is removed. In addition, not only the film 32 on the susceptor 217 but also the film 32 (which is not intended) formed on components in the process vessel, on an inner surface of the process vessel and the like are removed.

Incidentally, in order to increase a production efficiency of the process substrates 200 (that is, a substrate production efficiency), it is preferable to lower the temperature of the susceptor 217 as quickly as possible and to shorten a cooling process time. Therefore, according to the present embodiments, the first cooling substrate 300L and the second cooling substrate 300S (which are at a temperature lower than that of the susceptor 217) are placed on the susceptor 217 to lower the temperature of the susceptor 217. Thereby, it is possible to shorten a time taken until the film forming process of the subsequent process substrate 200 is started. As a result, it is possible to improve the production efficiency of the process substrates 200.

According to the present embodiments, as shown in FIG. 6B, the first cooling substrate 300L and the second cooling substrate 300S (whose diameters are smaller than that of the process substrate 200 and the diameter of the film 32 of the annular shape and configured to be capable of contacting the susceptor 217 over a narrower area than the process substrate 200) are placed inside the film 32 of the annular shape (which is unintentionally formed on the susceptor 217) with the center of the substrate (that is, the process substrate 200) and the center of the susceptor 217 aligned. Thereby, it is possible to deliver the cleaning gas to an entirety of the film 32 formed on the susceptor 217. Since the first cooling substrate 300L and the second cooling substrate 300S are placed inside the film 32 of the annular shape, the first cooling substrate 300L and the second cooling substrate 300S are naturally placed inside an outline of the susceptor 217. Therefore, not only the film 32 outside a range (radially outward) of the process substrate 200, but also the film 32 formed between the process substrate 200 and the susceptor 217 (in other words, the film 32 formed inside an outer periphery of the process substrate 200 (see FIG. 6A)) can be removed by the cleaning process.

### <Film Forming Process, Cooling Process and Cleaning Process in Substrate Processing Apparatus 1>

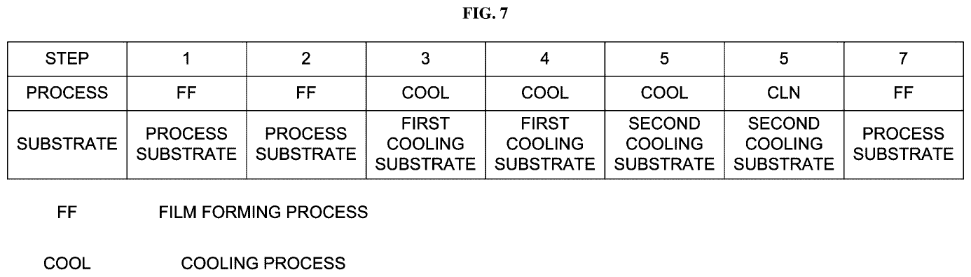

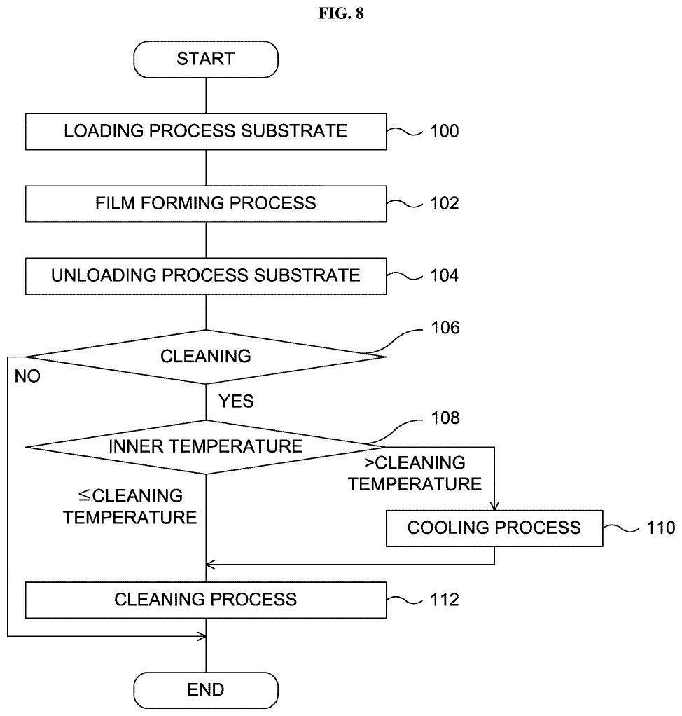

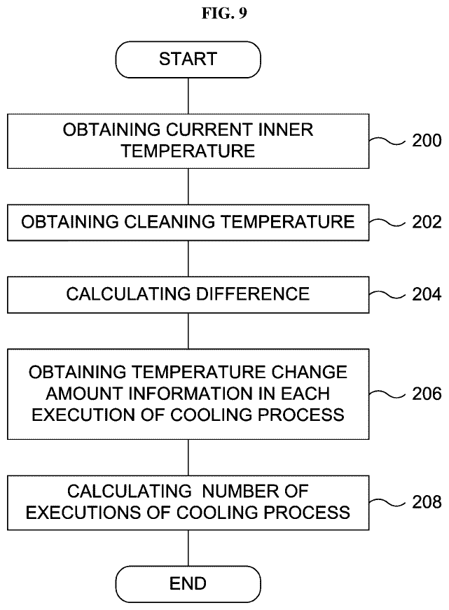

Hereinafter an overview of an example of a method of operating the film forming process and the cleaning process in the substrate processing apparatus 1 will be described by using a process table (explanatory diagram) of a processing process in FIG. 7 and a flow chart in FIG. 8. A processing shown in FIG. 8 (as well as processings shown in FIGS. 9 to 11 described below) is performed by the controller 400 according to procedures of a program.

As shown in FIG. 8, in a step 100, the process substrate 200 is loaded into the first process furnace 202 and placed on the susceptor 217.

Subsequently, in a step 102, the film forming process is performed on the process substrate 200 (substrate processing step; for example, steps 1 and 2 shown in FIG. 7).

Subsequently, in a step 104, after the film forming process is performed, the process substrate 200 is unloaded. In addition, when it is preferable to cool the process substrate 200, the process substrate 200 is transferred to the process substrate cooler 139 and cooled.

Subsequently, in a step 106, it is determined whether or not it is preferable to perform the cleaning process in the first process furnace 202. When it is determined that it is preferable to perform the cleaning process, a step 108 is performed. When it is determined that it is not preferable to perform the cleaning process, the processing shown in FIG. 8 is terminated.

In the step 108, a temperature (inner temperature) of the first process furnace 202 (in the present embodiments, the temperature of the susceptor 217) is measured by the radiation thermometer 264. When it is determined that the temperature of the susceptor 217 measured by the radiation thermometer 264 is higher than the cleaning temperature during the cleaning process, a step 110 is performed, and when it is determined that the temperature of the susceptor 217 is equal to or lower than the cleaning temperature during the cleaning process, the cooling process is terminated and a step 112 is performed (temperature comparison step). In the step 110, a cooling substrate (the first cooling substrate 300L or the second cooling substrate 300S) is placed on the susceptor 217 and the cooling process is performed (cooling substrate placement step and cooling step; for example, steps 3 to 5 shown in FIG. 7), and after the cooling process, the step 112 is performed. In the step 112, the cleaning process (cleaning step; for example, a step 6 shown in FIG. 7) for the first process furnace 202 is performed.

When the film forming process and the cleaning process for the process substrate 200 are completed in a manner described above, the film forming process for the subsequent process substrate 200 (a step 7 shown in FIG. 7) is performed. Then, the cooling process and the cleaning process are similarly performed on the subsequent process substrate 200. By performing each of the steps mentioned above in a manner described above, it is possible to rapidly cool the susceptor 217. As a result, it is possible to improve the production efficiency of the process substrates 200.

Subsequently, a method of calculating the number of executions of performing the cooling process (for example, the steps 3 to 5 shown in FIG. 7) will be described by using a flow chart shown in FIG. 9. First, in a step 200, a current temperature (current inner temperature) of the first process furnace 202 (in the present embodiments, the temperature of the susceptor 217) is obtained.

Subsequently, in a step 202, the cleaning temperature when the cleaning process is performed in the first process furnace 202 is obtained.

Subsequently, in a step 204, a difference between the current temperature of the susceptor 217 and the cleaning temperature is calculated (that is, the difference is obtained by subtracting the cleaning temperature from the current temperature of the susceptor 217).

Subsequently, in a step 206, as an example, temperature change amount information on an amount of a temperature change in each execution of the cooling process using the first cooling substrate 300L alone is obtained. In other words, information on how many degrees Celsius (° C.) the temperature of the susceptor 217 is lowered when the first cooling substrate 300L is placed can be obtained. In addition, the temperature change amount information is defined by a parameter, and for example, the amount of the temperature change obtained in a past execution may be used. Furthermore, when the first cooling substrate 300L is replaced a plurality of times, the amount of the temperature change from a previous execution may also be used.

Subsequently, in a step 208, the number of executions of the cooling process is calculated. In the present embodiments, for example, the number of executions of the cooling process is calculated based on the difference between the temperature of the susceptor 217 and the cleaning temperature, and the amount of the temperature change when the single execution of the cooling process is performed using the first cooling substrate 300L alone. For example, when the current temperature of the susceptor 217 is set to “A” ° C., the cleaning temperature is set to “B” ° C., the difference between the temperature of the susceptor 217 and the cleaning temperature is set to “C” ° C. (that is, “C” is obtained by subtracting “B” from “A”), the amount of the temperature change when the single execution of the cooling process is performed using the first cooling substrate 300L alone is set to “D” ° C., and the number of executions of the cooling process is set to “n”, the number of executions of the cooling process n can be obtained by using a relationship “C/D≤n” (where n is an integer obtained by calculating “C/D” and rounding up the decimal point).

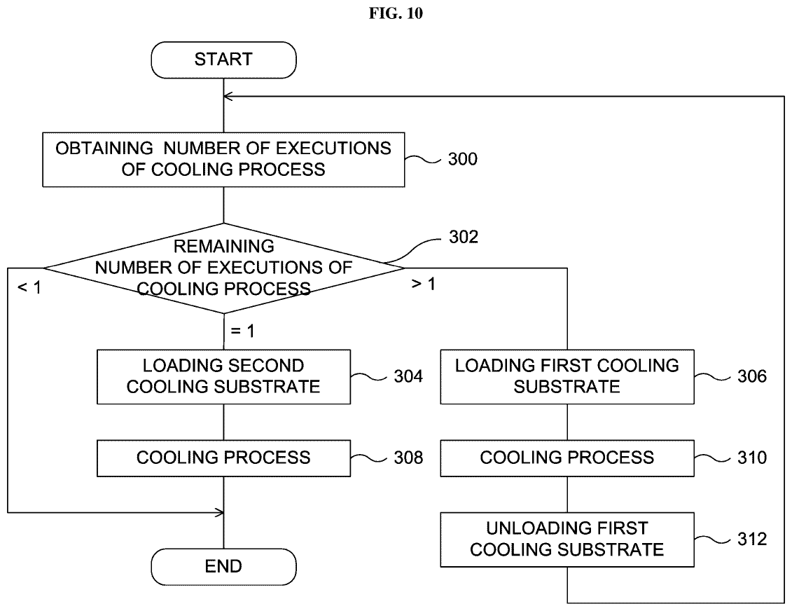

Subsequently, the cooling process (determination based on the number of executions of the cooling process) will be described using a flow chart shown in FIG. 10. First, in a step 300, the number of executions of the cooling process n is obtained.

Subsequently, in a step 302, the remaining number of executions of the cooling process is determined. When it is determined in the step 302 that the remaining number of executions of the cooling process is less than one, the cooling process is terminated. When it is determined that the remaining number of executions of the cooling process is one, a step 304 is performed. When it is determined that the remaining number of executions of the cooling process is greater than one, a step 306 is performed.

In the step 304, the first cooling substrate 300L (which is used) placed on the susceptor 217 is removed, and as a final execution of the cooling process, the second cooling substrate 300S accommodated in the cooling substrate cooler 300 is unloaded from the cooling substrate cooler 300 and placed on the susceptor 217. That is, the first cooling substrate 300L is replaced with the second cooling substrate 300S. After replacing the first cooling substrate 300L with the second cooling substrate 300S, a step 308 is performed.

In the step 308, the second cooling substrate 300S is placed on the susceptor 217 and subjected to the cooling process.

On the other hand, in the step 306, the first cooling substrate 300L (which is used) placed on the susceptor 217 is removed, and a new first cooling substrate among the first cooling substrates 300L unloaded from the cooling substrate cooler 300 is loaded and placed on the susceptor 217.

Subsequently, in a step 310, with the new first cooling substrate among the first cooling substrates 300L placed on the susceptor 217, the cooling process for the susceptor 217 is performed. After the cooling process for the susceptor 217 is completed, a step 312 is performed. In the step 312, the new first cooling substrate (which is used) among the first cooling substrates 300L is unloaded, and the step 300 is performed again. The first cooling substrate 300L (which is used) (and the new first cooling substrate which is used) is returned to the cooling substrate cooler 300, cooled, and reused. In a manner described above, the susceptor 217 is finally cooled by the second cooling substrate 300S.

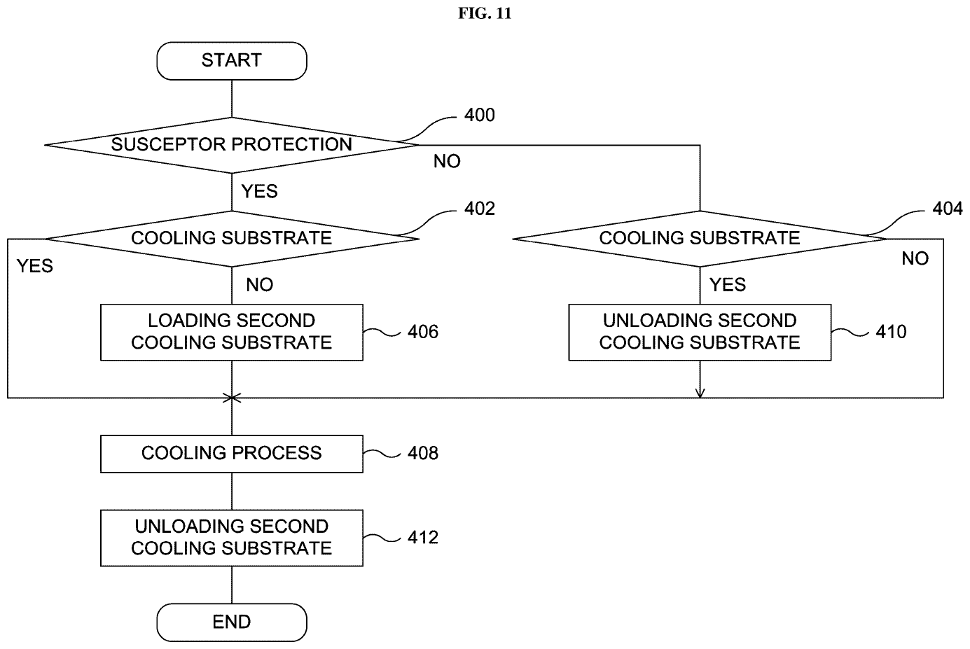

Subsequently, an example of the cleaning process for the first process furnace 202 will be described using a flow chart shown in FIG. 11. First, in a step 400, it is determined whether or not it is preferable to protect the surface of the susceptor 217 when performing the cleaning process for the susceptor 217.

When it is determined that it is preferable to protect the surface of the susceptor 217 in the step 400, a step 402 is performed. When it is determined that it is not preferable to protect the surface of the susceptor 217 in the step 400, a step 404 is performed.

In the step 402, it is determined whether or not the cooling substrate (the first cooling substrate 300L or the second cooling substrate 300S) is present on the susceptor 217. When it is determined in the step 402 that no cooling substrate is present, a step 406 is performed, and when it is determined that the cooling substrate is present, a step 408 is performed.

In the step 406, the second cooling substrate 300S is loaded into the first process furnace 202, and the second cooling substrate 300S is placed on the susceptor 217. After the second cooling substrate 300S is placed, the step 408 is performed. In the step 408, with the second cooling substrate 300S placed on the susceptor 217, the cleaning process is performed.

On the other hand, in the step 404, it is determined whether or not the cooling substrate is present on the susceptor 217. When it is determined in the step 404 that no cooling substrate is present, the step 408 is performed. In the step 408, the cleaning process for the first process furnace 202 is performed with no cooling substrate placed on the susceptor 217.

On the other hand, when it is determined in the step 404 that the cooling substrate is present on the susceptor 217, the step 410 is performed. In the step 410, the cooling substrate (for example, the second cooling substrate 300S) placed on the susceptor 217 is unloaded and returned to the cooling substrate cooler 300.

After the second cooling substrate 300S placed on the susceptor 217 is unloaded in the step 410, the step 408 is performed. As described above, in the step 408, the cleaning process for the first process furnace 202 is performed with no second cooling substrate 300S placed on the susceptor 217.

After the cleaning process in the step 408 is completed, a step 412 is performed. In the step 412, when the second cooling substrate 300S is placed on the susceptor 217, the second cooling substrate 300S is unloaded and returned to the cooling substrate cooler 300, and the processing shown in FIG. 11 is terminated. In addition, when the second cooling substrate 300S is not placed on the susceptor 217, the processing shown in FIG. 11 is terminated.

According to the present embodiments, it is possible to obtain one or more of the following effects. In the substrate processing apparatus 1 according to the present embodiments, since the susceptor 217 can be rapidly cooled by using a substrate dedicated to cooling (that is, the cooling substrate such as the first cooling substrate 300L and the second cooling substrate 300S), it is possible to contribute to improving the cooling efficiency. Further, in the cleaning process, since the cooling substrate used in the cooling process (for example, the second cooling substrate 300S) can be used as it is (that is, the cleaning process can be performed while the second cooling substrate 300S is placed on the susceptor 217), it is possible to shorten the time to perform the unloading of the cooling substrate. Thereby, it is possible to contribute to improving the production efficiency. In addition, since the susceptor 217 can be rapidly cooled to promptly start the cleaning process, it is possible to improve the production efficiency of the process substrates 200.

In the substrate processing apparatus 1 according to the present embodiments, the second cooling substrate 300S whose diameter is smaller than that of the process substrate 200 and smaller than that of the inner diameter of the film 32 (of the annular shape) unintentionally formed on the susceptor 217 can be used, and the second cooling substrate 300S can be disposed inside the film 32 (of the annular shape) so as not to cover the film 32. Thereby, the second cooling substrate 300S can be in close contact with the susceptor 217 over the entire surface of the second cooling substrate 300S, and the susceptor 217 can be cooled more efficiently as compared with a case where the second cooling substrate 300S is not in close contact with the susceptor 217.

In addition, in the substrate processing apparatus 1 according to the present embodiments, it is possible to perform the cleaning process for the susceptor 217 with the second cooling substrate 300S placed on the susceptor 217. By placing the second cooling substrate 300S on the susceptor 217, an area where the second cooling substrate 300S is placed is not contacted with the cleaning gas and is not cleaned. Therefore, it is possible to protect areas where the cleaning process is not preferable, and it is also possible to protect the susceptor 217. Thereby, it is possible to contribute to delaying a deterioration of the susceptor 217.

In addition, since the second cooling substrate 300S (whose diameter is smaller than the inner diameter of the film 32 of the annular shape) is placed inside the film 32 of the annular shape, by performing the cleaning process with the second cooling substrate 300S placed on the susceptor 217, it is possible to reliably remove the film 32 which is unintentionally formed.

By setting the diameter of the first cooling substrate 300L and the diameter of the second cooling substrate 300S to 90% or more and 99% or less of the diameter of the process substrate 200, it is possible to arrange (dispose) the first cooling substrate 300L and the second cooling substrate 300S inside the film 32 (which is unintentionally formed on the susceptor 217 to intrude into an outline of the process substrate 200 that defines an area on the susceptor 217 occupied by the process substrate 200 when the process substrate 200 is placed on the susceptor 217). For example, as the diameter of the first cooling substrate 300L and the diameter of the second cooling substrate 300S become smaller, a cooling capacity of the susceptor 217 decreases and the area provided to protect the susceptor 217 becomes smaller. Therefore, it is preferable to set the diameter of the first cooling substrate 300L and the diameter of the second cooling substrate 300S to 90% or more of the diameter of the process substrate 200. In addition, by setting the diameter of the first cooling substrate 300L and the diameter of the second cooling substrate 300S to 99% or less of the diameter of the process substrate 200, it is possible to prevent the film 32 (which is unintentionally formed on the susceptor 217) from being covered.

By placing the first cooling substrate 300L and the second cooling substrate 300S inside the outline of the susceptor 217, it is possible to prevent the film 32 (which is unintentionally formed on the susceptor 217) from being covered. In addition, it is preferable to place the process substrate 200, the first cooling substrate 300L and the second cooling substrate 300S on the susceptor 217 such that the center of the process substrate 200, a center of the first cooling substrate 300L and a center of the second cooling substrate 300S coincide with the center of the susceptor 217.

By placing the first cooling substrate 300L and the second cooling substrate 300S inside the outline (outer peripheral edge) of the process substrate 200 (wherein the outline of the process substrate 200 defines the area on the susceptor 217 occupied by the process substrate 200 when the process substrate 200 is placed on the susceptor 217), the film 32 of the annular shape (which is unintentionally formed on the susceptor 217) is not covered.

When the cooling substrate (the first cooling substrate 300L or the second cooling substrate 300S) alone is placed on the susceptor 217 and the cooling process is performed, the temperature of the susceptor 217 may not be lowered to a temperature at which the cleaning process can be performed. According to the present embodiments, the cooling process can be performed a plurality of times by preparing the plurality of first cooling substrates 300L (which have been cooled in the cooling substrate cooler 300) and by replacing the first cooling substrate 300L with the new first cooling substrate among the first cooling substrates 300L (alternatively, the second cooling substrate 300S may be placed finally). Thereby, it is possible to rapidly and efficiently lower the temperature of the susceptor 217.

While the temperature of the susceptor 217 does not reach the temperature at which the cleaning process can be performed, the first cooling substrate 300L can be repeatedly replaced with the new first cooling substrate among the first cooling substrates 300L (alternatively, the second cooling substrate 300S may be placed finally). Thereby, it is possible to rapidly lower the temperature of the susceptor 217 to the temperature at which the cleaning process can be performed. As a result, it is possible to contribute to improving the cooling efficiency.

In the substrate processing apparatus 1, during the cooling process, the first cooling substrate 300L and the second cooling substrate 300S (which are different in size) may be switched in accordance with the temperature of the susceptor 217. That is, when there is a large difference between the temperature of the susceptor 217 and the temperature at which the cleaning process can be performed, the first cooling substrate 300L whose diameter is greater than that of the second cooling substrate 300S (in other words, the first cooling substrate 300L whose cooling capacity is greater than that of the second cooling substrate 300S whose diameter is relatively small) is placed on the susceptor 217 at first. Thereby, it possible to increase a rate at which the temperature of the susceptor 217 is lowered. As a result, it is possible to quickly and efficiently cool the susceptor 217.

During the cooling process, when the temperature of the susceptor 217 is higher than the temperature at which the cleaning process can be performed, it is preferable to select the first cooling substrate 300L whose diameter is close to that of the process substrate 200. Comparing the first cooling substrate 300L whose diameter is close to that of the process substrate 200 with the second cooling substrate 300S whose diameter is smaller than that of the first cooling substrate 300L, the cooling capacity of the first cooling substrate 300L (whose diameter is close to that of the process substrate 200) is higher than that of the second cooling substrate 300S. Therefore, during the cooling process, when the temperature of the susceptor 217 is higher than the temperature at which the cleaning process can be performed, the first cooling substrate 300L (whose diameter is close to that of the process substrate 200) is selected and used first. Thereby, it is possible to rapidly and efficiently cool the susceptor 217.

Assuming that the cleaning processing is performed with the process substrate 200 placed on the susceptor 217, in order to rapidly lower the temperature of the susceptor 217, first, the cooling process is performed using the first cooling substrate 300L, and finally, the cooling processing is performed by replacing the first cooling substrate 300L with the second cooling substrate 300S. Thereby, it is possible to remove the film 32 (which is unintentionally formed on the susceptor 217) while the second cooling substrate 300S is still placed on the susceptor 217. In addition, it is possible to omit the unloading (removing) of the second cooling substrate 300S before the cleaning process. Thereby, it is possible to contribute to improving a work efficiency.

In addition, when the temperature of the susceptor 217 reaches the temperature at which the cleaning process can be performed, the cooling process is terminated. Thereby, it is possible to promptly start the cleaning process without redundantly performing the cooling process on the susceptor 217.

When it is preferable to perform the cooling process a plurality of times, as in the cooling substrate cooler 300 according to the present embodiments, it is preferable to provide the support 322 capable of supporting the first cooling substrate 300L and the second cooling substrate 300S in a multistage manner in the accommodation chamber 304 (where the plurality of first cooling substrates 300L and the plurality of second cooling substrates 300S to be used in the cooling process are accommodated). In addition, since the first cooling substrate 300L and the second cooling substrate 300S are transferred and received between the cooling substrate cooler 300 and the first process furnace 202, it is preferable to provide the cooling substrate cooler 300 such that the cooling substrate cooler 300 is connected to the first transfer chamber 103 as in the present embodiments (see FIG. 1).

In addition, when the cooling process is performed a plurality of times, by replacing the cooling substrate that has completed the cooling process (for example, the first cooling substrate 300L placed on the susceptor 217) with another cooling substrate (for example, the first cooling substrate 300L and the second cooling substrate 300S accommodated in the accommodation chamber 304), it is possible to use the cooling substrate (for example, the first cooling substrate 300L or the second cooling substrate 300S) (which is completely cooled) for the cooling process for the susceptor 217.

In the cooling substrate cooler 300 according to the present embodiments, the support 322 capable of supporting the substrates in a multistage manner in the vertical direction is provided, and the elevator 328 capable of elevating and lowering the support 322 in the vertical direction is also provided. As a result, by elevating and lowering the support 322 in the vertical direction, it is possible to easily transfer the first cooling substrate 300L and the second cooling substrate 300S by using the first wafer transfer structure 112.

The supply pipe 312 capable of supplying the cooling gas and the exhaust pipe 314 through which the gas in the accommodation chamber 304 is exhausted are connected to the accommodation chamber 304. Therefore, by supplying and exhausting the cooling gas to and from the accommodation chamber 304, it is possible to rapidly cool the first cooling substrate 300L and the second cooling substrate 300S (that is, for example, which is warmed by performing the cooling process and returned to the accommodation chamber 304).

According to a program of the present embodiments, for example, by using the computer, it is possible to perform the processing described above by using the configurations (components) mentioned above.

### Other Embodiments of Present Disclosure

While the technique of the present disclosure is described in detail by way of the embodiments mentioned above, the technique of the present disclosure is not limited thereto and may be modified in various ways without departing from the scope thereof.

For example, the embodiments mentioned above are described by way of an example in which the first process furnace 202 is cooled using the first cooling substrate 300L and the second cooling substrate 300S whose diameter is different from that of the first cooling substrate 300L. However, the technique of the present disclosure is not limited thereto. For example, the susceptor 217 may also be cooled using the cooling substrates whose diameter is substantially the same as that of the first cooling substrate 300L or that of the second cooling substrate 300S.

In addition, a thickness of the first cooling substrate 300L may be set to be thicker than a thickness of the second cooling substrate 300S. In such a case, it is possible to further increase the cooling capacity of each of the first cooling substrates 300L, and as a result, it is also possible to reduce the number of times of replacing the first cooling substrate 300L. For example, when doubling the thickness of the first cooling substrate 300L, it is possible to reduce the number of times of replacing the first cooling substrate 300L by half. That is, it is possible to appropriately change the thickness and the diameter of the first cooling substrate 300L and the thickness and the diameter of the second cooling substrate 300S.

For example, a plurality of cooling substrate coolers including the cooling substrate cooler 300 may be provided.

The technique of the present disclosure may also be applied to other types of substrate processing apparatuses whose configurations are different from that of the substrate processing apparatus 1 in which the process substrate 200 is placed on the susceptor 217 to perform the film forming process. Even in such a case, process procedures and process conditions of each process using the substrate processing apparatuses exemplified above may be substantially the same as those of the embodiments mentioned above. Even in such a case, it is possible to obtain substantially the same effects as in the embodiments mentioned above. For example, the embodiments mentioned above are described by way of an example in which the cooling substrate cooler 300 mentioned above is configured to cool the first cooling substrate 300L and the second cooling substrate 300S by supplying the cooling gas into the housing thereof. However, for example, the cooling substrate cooler 300 may be configured similar to a refrigerator to cool the first cooling substrate 300L and the second cooling substrate 300S without supplying the cooling gas. In addition, the technique of the present disclosure is not limited to the substrate processing apparatus. For example, the technique of the present disclosure may also be applied to an apparatus such as an LCD (Liquid Crystal Display) manufacturing apparatus and a solar panel manufacturing apparatus.

Further, the entire contents of Japanese Patent Application No. 2022-123008, filed on Aug. 1, 2022, are hereby incorporated in the present specification by reference. All documents, patent applications, and technical standards described in the present specification are hereby incorporated in the present specification by reference to the same extent that the contents of each of the documents, the patent applications and the technical standards are specifically described.

As described above, according to some embodiments of the present disclosure, it is possible to improve the substrate production efficiency by rapidly cooling the process vessel.

What is claimed is:

1. A substrate processing apparatus comprising:
a process vessel in which a process substrate is capable of being processed;
a substrate placement table on which the process substrate is capable of being placed; and
a controller configured to be capable of controlling a cooling process and a cleaning process such that the cooling process of cooling an inner portion of the process vessel is performed with a cooling substrate placed on the substrate placement table when an inner temperature of the process vessel after processing the process substrate is higher than a temperature for the cleaning process of cleaning the inner portion of the process vessel, wherein an outer peripheral length of the cooling substrate is set to be shorter than that of the process substrate, and such that the cleaning process is performed when the inner temperature of the process vessel reaches a temperature at which the cleaning process is possible.

2. The substrate processing apparatus of claim 1, wherein the cleaning process is performed with the cooling substrate placed on the substrate placement table.

3. The substrate processing apparatus of claim 2, wherein the outer peripheral length of the cooling substrate is set to be 90% or more and 99% or less of that of the process substrate.

4. The substrate processing apparatus of claim 3, wherein the cooling substrate is placed inside an outline of the substrate placement table.

5. The substrate processing apparatus of claim 3, wherein the cooling substrate is placed inside an outline of the process substrate that defines an area on the substrate placement table occupied by the process substrate when the process substrate is placed on the substrate placement table.

6. The substrate processing apparatus of claim 1, wherein a plurality of cooling substrates comprising the cooling substrate are provided, and the cooling process is performed by replacing between the plurality of cooling substrates.

7. The substrate processing apparatus of claim 6, wherein the controller is further configured to be capable of controlling the cooling process and the cleaning process such that the plurality of cooling substrates are repeatedly replaced therebetween while the inner temperature of the process vessel does not reach the temperature at which the cleaning process is possible.

8. The substrate processing apparatus of claim 7, wherein the controller is further configured to be capable of controlling the cooling process and the cleaning process such that, during the cooling process, the cooling substrate is replaced with another cooling substrate whose outer peripheral length is different therefrom in accordance with the inner temperature of the process vessel.

9. The substrate processing apparatus of claim 8, wherein the controller is further configured to be capable of controlling the cooling process and the cleaning process such that, during the cooling process, a first cooling substrate whose outer peripheral length is close to that of the process substrate is selected among the plurality of cooling substrates when the inner temperature of the process vessel is higher than the temperature at which the cleaning process is possible.

10. The substrate processing apparatus of claim 8, wherein a first cooling substrate and a second cooling substrate whose outer peripheral length is shorter than that of the first cooling substrate are provided, and
wherein the controller is further configured to be capable of controlling the cooling process and the cleaning process such that, when it is determined that a final execution of the cooling process is to be performed, the final execution of the cooling process is performed by replacing the first cooling substrate placed on the substrate placement table with the second cooling substrate.

11. The substrate processing apparatus of claim 1, wherein the controller is further configured to be capable of controlling the cooling process and the cleaning process such that the cooling process is terminated when the inner temperature of the process vessel reaches the temperature at which the cleaning process is possible.

12. The substrate processing apparatus of claim 1, further comprising:
an accommodation chamber capable of accommodating a plurality of cooling substrates comprising the cooling substrate,
wherein the accommodation chamber is provided with a support capable of supporting the plurality of cooling substrates in a multistage manner.

13. The substrate processing apparatus of claim 12, wherein the controller is further configured to be capable of controlling the cooling process and the cleaning process such that, during the cooling process, the cooling substrate placed on the substrate placement table is replaced with another cooling substrate accommodated in the accommodation chamber.

14. The substrate processing apparatus of claim 12, wherein the support is provided with an elevator configured to be capable of elevating and lowering the support capable of supporting the plurality of cooling substrates.

15. The substrate processing apparatus of claim 12, wherein the accommodation chamber is provided with a pipe through which a cooling gas is capable of being supplied, and the accommodation chamber is capable of cooling the plurality of cooling substrates by the cooling gas.

16. A cleaning method comprising:
(a) comparing an inner temperature of a process vessel with a temperature at which a cleaning process of cleaning an inner portion of the process vessel is possible, wherein the process vessel is provided with a substrate placement table on which a process substrate is capable of being placed;
(b) placing a cooling substrate on the substrate placement table when the inner temperature of the process vessel is higher than a temperature for the cleaning process, wherein an outer peripheral length of the cooling substrate is set to be shorter than that of the process substrate and the cooling substrate is configured to be capable of cooling the substrate placement table;
(c) cooling the inner portion of the process vessel; and
(d) performing the cleaning process when the inner temperature of the process vessel reaches the temperature at which the cleaning process is possible.

17. A method of manufacturing a semiconductor device, comprising the method of claim 16.

18. A non-transitory computer-readable recording medium storing a program that causes a substrate processing apparatus, by a computer, to perform:
(a) comparing an inner temperature of a process vessel with a temperature at which a cleaning process of cleaning an inner portion of the process vessel is possible, wherein the process vessel is provided with a substrate placement table on which a process substrate is capable of being placed;
(b) placing a cooling substrate on the substrate placement table when the inner temperature of the process vessel is higher than a temperature for the cleaning process, wherein an outer peripheral length of the cooling substrate is set to be shorter than that of the process substrate and the cooling substrate is configured to be capable of cooling the substrate placement table;
(c) cooling the inner portion of the process vessel; and
(d) performing the cleaning process when the inner temperature of the process vessel reaches the temperature at which the cleaning process is possible.
